(19) United States
(12) Patent Application Publication
(10) Pub. No.: US 2016/0336490 A1
(43) Pub. Date: Nov. 17, 2016

(54) METHODS FOR PREPARING QUANTUM DOTS WITH INSULATOR COATINGS

(71) Applicants: Weiwen Zhao, Happy Valley, OR (US); Kari Haley, Portland, OR (US); Juanita N. Kurtin, Hillsboro, OR (US)

(72) Inventors: Weiwen Zhao, Happy Valley, OR (US); Kari Haley, Portland, OR (US); Juanita N. Kurtin, Hillsboro, OR (US)

(21) Appl. No.: 15/156,242

(22) Filed: May 16, 2016

Related U.S. Application Data
(60) Provisional application No. 62/162,318, filed on May 15, 2015.

(51) Int. Cl. H01L 33/50; C09K 11/62; C09K 11/02; C09K 11/88

(52) U.S. Cl. CPC H01L 33/502; C09K 11/883; C09K 11/621; C09K 11/025; H01L 2933/0033; H01L 2933/0041

(57) ABSTRACT

A method of fabricating a semiconductor structure comprises forming a quantum dot. An insulator layer of silica is then formed encapsulating the quantum dot to create a coated quantum dot, using a reverse micelle sol-gel reaction. In one embodiment, the reverse micelle sol-gel reaction includes dissolving the quantum dot in a first non-polar solvent to form a first solution, adding the first solution to a second solution having a surfactant dissolved in a second non-polar solvent; and adding sodium silicate, potassium silicate, or lithium silicate to the second solution.

### CROSS-REFERENCE TO RELATED APPLICATIONS

This application claims the benefit of U.S. Provisional Application No. 62/162,318, filed May 15, 2015, the entire contents of which are hereby incorporated by reference herein.

### BACKGROUND

In order to be integrated into a final product, quantum dots require a barrier between their surface and a matrix material in which they are encapsulated, for multiple reasons. The integration of the quantum dots into a product may require certain chemical compatibility, compatibility during downstream processing, and ultimately compatibility with the matrix material (for example, a plastic or a gel) used for quantum dot encapsulation. Without such compatibility, the quantum dots are likely to degrade or aggregate and/or redistribute themselves within the matrix material, a generally undesirable occurrence in, for example, a solid state lighting product. Additionally, for performance reasons, protection of the quantum dot surface is typically required, as it is a method to maintain an electronically uniform environment, ensure that the density of non-radiative pathways (traps) is minimized, and that the environment does not change over the course of the product lifetime. Furthermore, protecting the quantum dot surface minimizes further chemical reaction with environmental degradants, such as oxygen. This can be particularly important for light-emitting-diode (LED) applications, where the quantum dot must tolerate temperatures as high as 200 degrees Celsius and constant high-intensity illumination with high-energy light. However, the weak surface bonding of many standard quantum dot ligands are non-ideal for the processing and long-term performance required of an LED product, for all the reasons listed above.

### SUMMARY

A semiconductor structure is fabricated by first forming a quantum dot. An insulator layer is then formed to encapsulate the quantum dot.

### BRIEF DESCRIPTION OF THE DRAWINGS

FIG. 1 is an image from a Transmission Electron Microscope (TEM) of a quantum dot coated with an insulator layer according to an embodiment of the invention.

FIG. 2A is a method of forming an insulator layer encapsulating a quantum dot according to an embodiment of the invention.

FIG. 2B is a method of forming an insulator layer encapsulating a quantum dot according to another embodiment of the invention.

FIG. 2C is a method of forming an insulator layer encapsulating a quantum dot according to yet another embodiment of the invention.

FIG. 2D is a method of forming an insulator layer encapsulating a quantum dot according to an additional embodiment of the invention.

FIG. 2E is a method of forming an insulator layer encapsulating a quantum dot according to a final embodiment of the invention.

FIG. 3A is a flow diagram in accordance with an embodiment of the invention.

FIG. 3B is a flow diagram in accordance with an embodiment of the invention.

FIG. 3C is a flow diagram in accordance with an embodiment of the invention.

FIG. 4 is an illustration of a semiconductor structure that has a nanocrystalline core and nanocrystalline shell pairing with one compositional transition layer, in accordance with an embodiment of the invention.

FIG. 5 illustrates a nano-particle in accordance with an embodiment of the invention.

### DETAILED DESCRIPTION

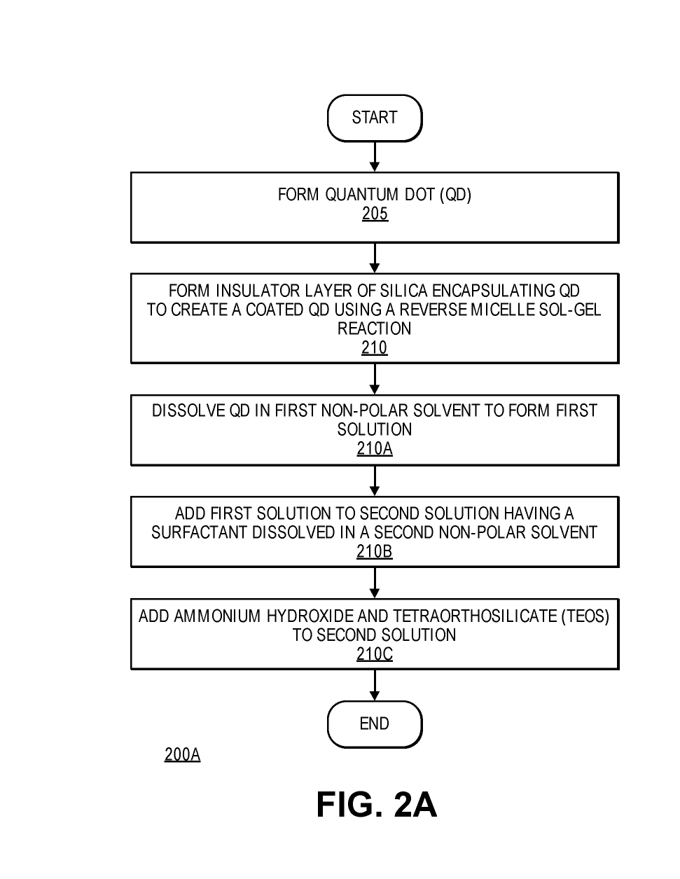

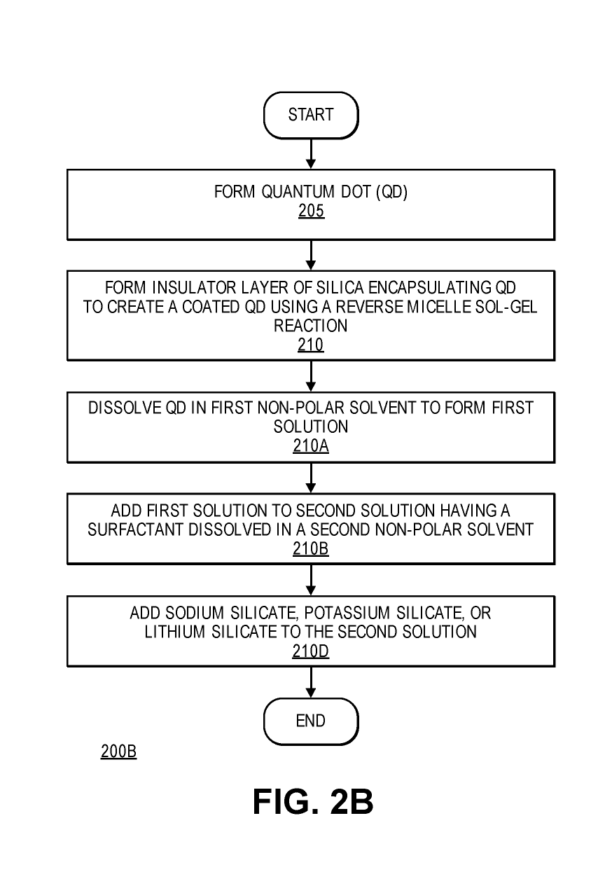

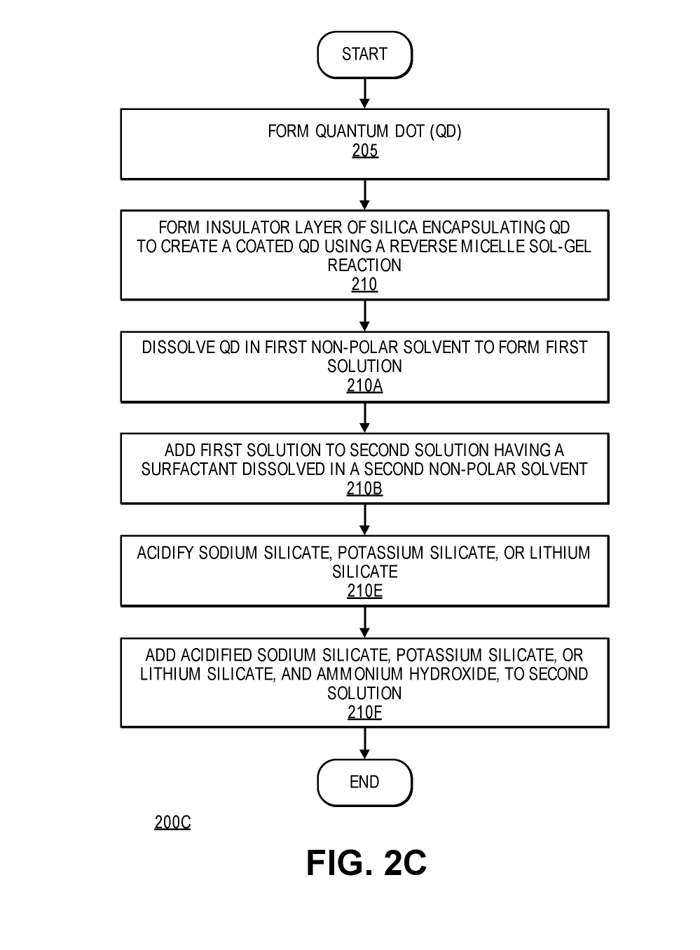

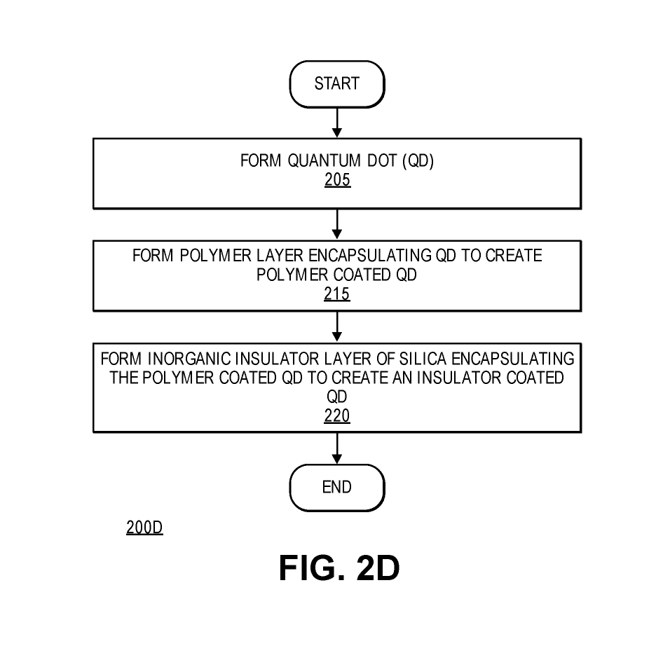

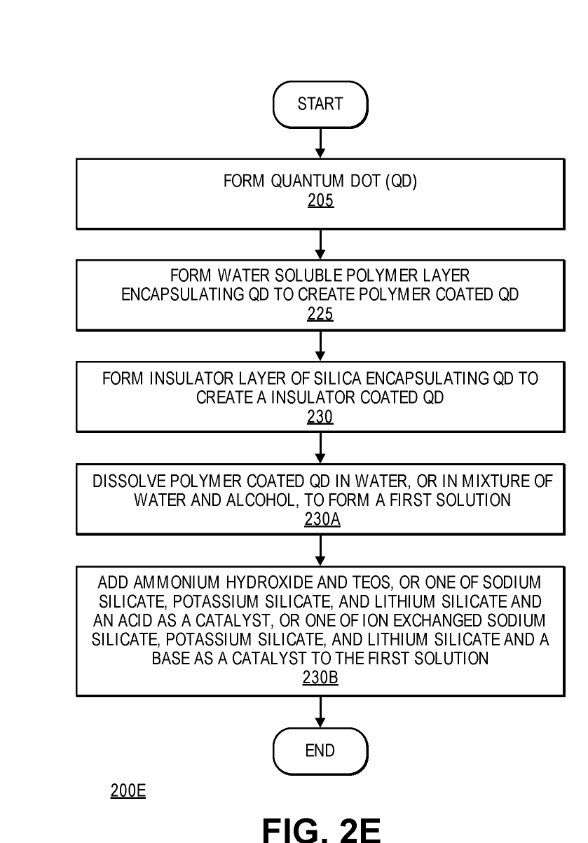

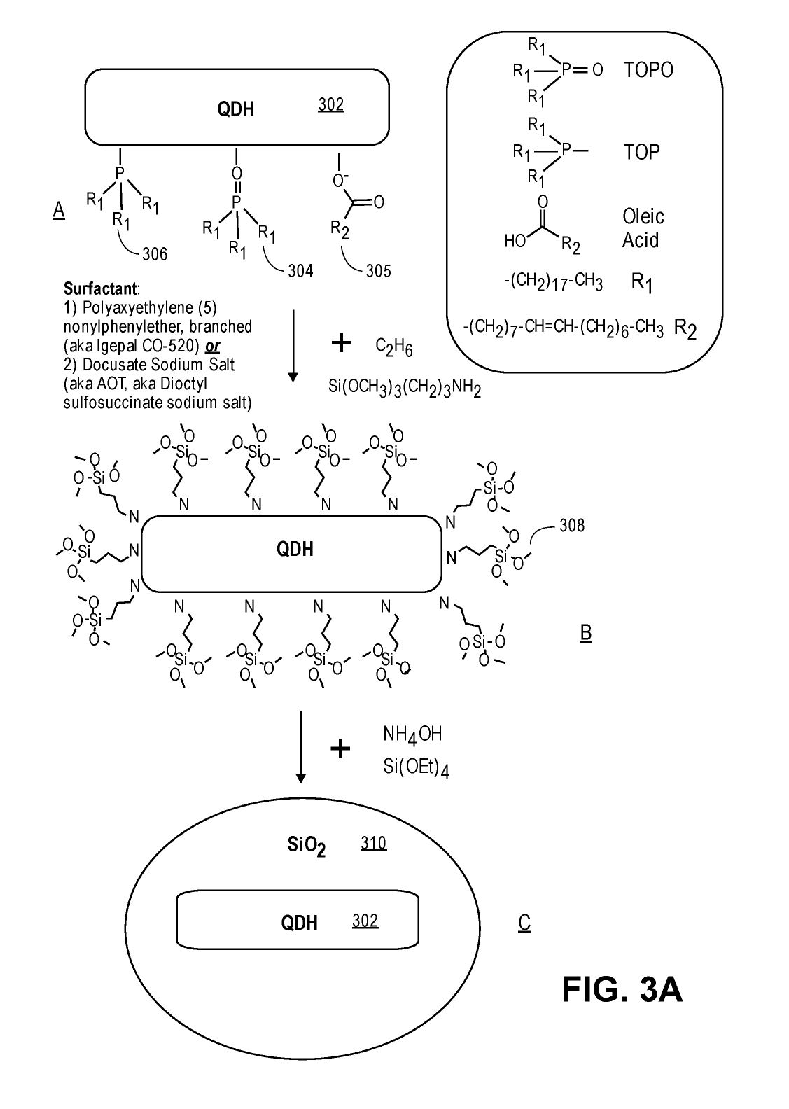

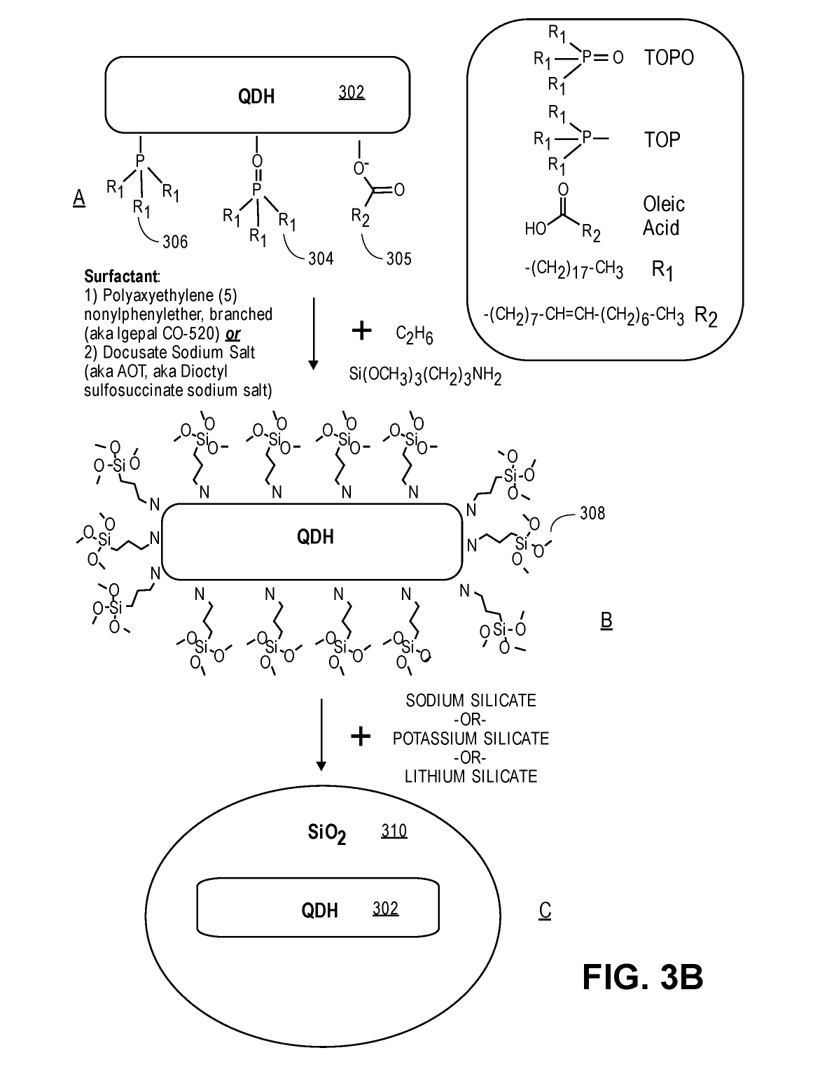

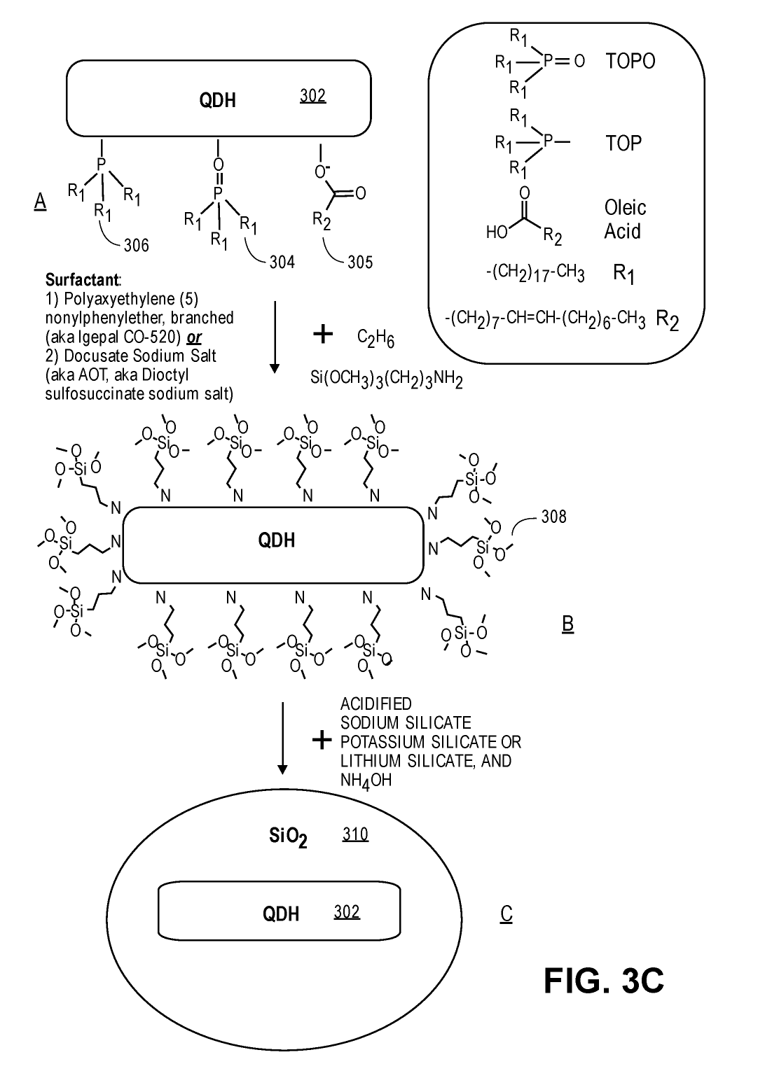

Quantum dots are materials which are beneficial in many applications, but which often cannot withstand thousands of hours of operation under the environmental and operating conditions of many products, for example, light emitting diode (LED) or solar devices. According to embodiments of the invention, quantum dots are made robust for certain applications by individually coating the surfaces of the quantum dots with an insulating layer of metal oxide (for example silica, titania, alumina, etc.). An example of quantum dots with an insulator layer is described below with reference to FIGS. 2A-2E and 3A-3C. However, this insulating layer may not be sufficient to protect the quantum dots in all operating or environmental conditions, due to the imperfect or porous coverage of the metal oxide. Adding another layer of metal oxide or other insulating material makes the quantum dots more robust, and thermally stable, by further protecting the surfaces and filling in any imperfections or pores.

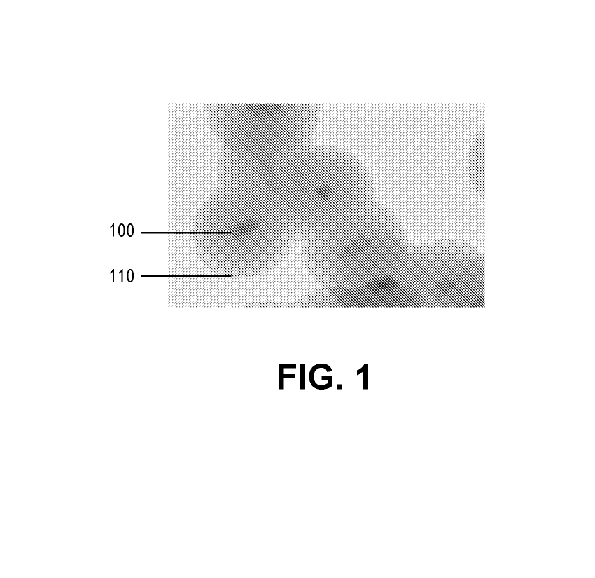

Additionally, in order to ensure that there is no self-quenching of photoluminescence or other interactions between or among quantum dots, in one embodiment, the first insulating layer serves as an adjustable spacer that allows the quantum dots to remain fully dispersed and spaced apart prior to adding a second insulating layer. By adding a metal oxide insulating layer by a reverse micelle or similar process, the individual quantum dots 100 are coated with enough material 110 to ensure adequate monodispersity, as seen in the Transmission Electron Microscope (TEM) image in FIG. 1, and avoid self-quenching.

In embodiments of the present invention, new methods are used to coat core/shell quantum dots with an insulating layer comprising materials including silica and other ligands to provide a structure having a high PLQY, high photostability, and excellent processibility. The insulating layer coating is applied using varying versions of sol-gel processing methods, all of which encapsulate each quantum dot individually into insulating layers, resulting in a very stable population of high performance quantum dot particles.

In a general embodiment, a semiconductor structure includes a nanocrystalline core composed of a first semiconductor material. The semiconductor structure also includes a nanocrystalline shell composed of a second, different, semiconductor material at least partially surrounding the nanocrystalline core. Additional nanocrystalline shells may also be formed that surround the core/shell pairing. An insulator layer encapsulates, e.g., coats, the nanocrystalline shell(s) and nanocrystalline core. Thus, coated semiconductor structures include coated structures such as the quantum dots described above. For example, in an embodiment, the nanocrystalline core is anisotropic, e.g., having an aspect ratio between, but not including, 1.0 and 2.0. In another example, in an embodiment, the nanocrystalline core is anisotropic and is asymmetrically oriented within the nanocrystalline shell. In an embodiment, the nanocrystalline core and the nanocrystalline shell(s) form a quantum dot.

In any case, the insulator layer may individually encapsulate each nanocrystalline shell/nanocrystalline core pairing. In an embodiment, the semiconductor structure further includes a nanocrystalline outer shell at least partially surrounding the nanocrystalline shell, between the nanocrystalline shell and the insulator layer. The nanocrystalline outer shell is composed of a third semiconductor material different from the semiconductor material of the shell and, possibly, different from the semiconductor material of the core.

With reference to the above described coated nanocrystalline core and nanocrystalline shell(s) pairings, in an embodiment, the insulator layer is bonded directly to the nanocrystalline shell. In one such embodiment, the insulator layer passivates an outermost surface of the nanocrystalline shell. In another embodiment, the insulator layer provides a barrier for the nanocrystalline shell and nanocrystalline core impermeable to an environment outside of the insulator layer.

With reference again to the above described coated nanocrystalline core and nanocrystalline shell pairings, in an embodiment, the insulator layer comprises a layer of material such as, but not limited to, silica (SiOx), titanium oxide (TiOx), zirconium oxide (ZrOx), alumina (AlOx), or hafnia (HfOx). In one such embodiment, the layer is silica having a thickness approximately in the range of 3-500 nanometers. In an embodiment, the insulator layer is an amorphous layer.

With reference again to the above described coated nanocrystalline core and nanocrystalline shell pairings, in an embodiment, an outer surface of the insulator layer is ligand-free. However, in an alternative embodiment, an outer surface of the insulator layer is ligand-functionalized. In one such embodiment, the outer surface of the insulator layer is ligand-functionalized with a ligand such as, but not limited to, a silane having one or more hydrolyzable groups or a functional or non-functional bipodal silane. In another such embodiment, the outer surface of the insulator layer is ligand functionalized with a ligand such as, but not limited to, mono-, di-, or tri-alkoxysilanes with three, two or one inert or organofunctional substituents of the general formula (R1O)3SiR2; (R1O)2SiR2R3; (R1O) SiR2R3R4, where R1 is methyl, ethyl, propyl, isopropyl, or butyl, R2, R3 and R4 are identical or different and are H substituents, alkyls, alkenes, alkynes, aryls, halogeno-derivates, alcohols, (mono, di, tri, poly) ethyleneglycols, (secondary, tertiary, quaternary) amines, diamines, polyamines, azides, isocyanates, acrylates, metacrylates, epoxies, ethers, aldehydes, carboxylates, esters, anhydrides, phosphates, phosphines, mercaptos, thiols, sulfonates, and are linear or cyclic, a silane with the general structure (R1O)3Si—(CH2)n-R—(CH2)n-Si(RO)3 where R and R1 is H or an organic substituent selected from the group consisting of alkyls, alkenes, alkynes, aryls, halogeno-derivates, alcohols, (mono, di, tri, poly) ethyleneglycols, (secondary, tertiary, quaternary) amines, diamines, polyamines, azides, isocyanates, acrylates, metacrylates, epoxies, ethers, aldehydes, carboxylates, esters, anhydrides, phosphates, phosphines, mercaptos, thiols, sulfonates, and are linear or cyclic, a chlorosilane, or an azasilane.

In another such embodiment, the outer surface of the insulator layer is ligand-functionalized with a ligand such as, but not limited to, organic or inorganic compounds with functionality for bonding to a silica surface by chemical or non-chemical interactions such as but not limited to covalent, ionic, H-bonding, or Van der Waals forces. In yet another such embodiment, the outer surface of the insulator layer is ligand-functionalized with a ligand such as, but not limited to, the methoxy and ethoxy silanes (MeO)3SiAllyl, (MeO)3SiVinyl, (MeO)2SiMeVinyl, (EtO)3SiVinyl, EtOSi(Vinyl)3, mono-methoxy silanes, chloro-silanes, or 1,2-bis-(triethoxysilyl)ethane.

In any case, in an embodiment, the outer surface of the insulator layer is ligand-functionalized to impart solubility, dispersability, heat stability, photo-stability, or a combination thereof, to the semiconductor structure. For example, in one embodiment, the outer surface of the insulator layer includes OH groups suitable for reaction with an intermediate linker to link small molecules, oligomers, polymers or macromolecules to the outer surface of the insulator layer, the intermediate linker one such as, but not limited to, an epoxide, a carbonyldiimidazole, a cyanuric chloride, or an isocyanate.

With reference again to the above described coated nanocrystalline core and nanocrystalline shell pairings, in an embodiment, the nanocrystalline core has a diameter approximately in the range of 2-6 nanometers. The nanocrystalline shell has a long axis and a short axis, the long axis having a length approximately in the range of 6-40 nanometers, and the short axis having a length approximately in the range of 1-10 nanometers greater than the diameter of the nanocrystalline core. The insulator layer has a thickness approximately in the range of 1-50 nanometers along an axis co-axial with the long axis and has a thickness approximately in the range of 3-50 nanometers along an axis co-axial with the short axis. In other embodiments, the thickness of the insulator layer may be greater than 50 nanometers, for example, up to 500 nanometers.

A lighting apparatus may include a light emitting diode and a plurality of semiconductor structures that, for example, act to down convert light absorbed from the light emitting diode. For example, in one embodiment, each semiconductor structure includes a quantum dot having a nanocrystalline core composed of a first semiconductor material and a nanocrystalline shell composed of a second, different, semiconductor material at least partially surrounding the nanocrystalline core. Each quantum dot has a photoluminescence quantum yield (PLQY) of at least 90%. An insulator layer encapsulates each quantum dot.

As described briefly above, and with respect to FIG. 2A, according to embodiment 200A, a quantum dot is formed 205 as described above, including, for example, at least one nanocrystalline shell and anisotropic nanocrystalline core. Then at 210 an insulator layer may be formed to encapsulate a quantum dot structure. For example, in an embodiment, a layer of silica is formed using a reverse micelle sol-gel reaction. In one such embodiment, using the reverse micelle sol-gel reaction includes dissolving the nanocrystalline shell/nanocrystalline core pairing in a first non-polar solvent to form a first solution at 210A. Subsequently, the first solution is added along with a species such as, but not limited to, 3-aminopropyltrimethoxysilane (APTMS), 3-mercapto-trimethoxysilane, or a silane comprising a phosphonic acid or carboxylic acid functional group, to a second solution having a surfactant dissolved in a second non-polar solvent at 210B. Subsequently, ammonium hydroxide and tetraorthosilicate (TEOS) are added to the second solution at 210C.

Thus, semiconductor nanocrystals coated with silica according to the present invention may be made by a sol-gel reaction such as a reverse micelle method. As an example, FIG. 3A illustrates operations in a reverse micelle approach to coating a semiconductor structure, in accordance with an embodiment of the present invention. Referring to part A of FIG. 3A, a quantum dot heterostructure (QDH) 302 (e.g., a nanocrystalline core/shell pairing) has attached thereto one or more of TOPO ligands 304, TOP ligands 306, and Oleic Acid 305. Referring to part B, the plurality of TOPO ligands 304, TOP ligands 306, and Oleic acid 305 are exchanged with a plurality of Si(OCH3)3(CH2)3NH2 ligands 308. The structure of part B is then reacted with TEOS (Si(OEt)4) and ammonium hydroxide (NH4OH) to form a silica coating 310 surrounding the QDH 302, as depicted in part C of FIG. 3A.

Silica Coating in Non-Polar Solvent Using Sodium Silicate, Potassium Silicate or Lithium Silicate as Silica Precursor.

With respect to FIG. 2B, according to embodiment 200B, a quantum dot is formed 205 as described above, including, for example, at least one nanocrystalline shell and anisotropic nanocrystalline core. Then at 210 an insulator layer is formed to encapsulate the quantum dot structure. For example, in an embodiment, a layer of silica is formed using a reverse micelle sol-gel reaction. According to embodiment 200B, instead of TEOS, Sodium silicate, Na2SiO3, also known as waterglass, can be used to prepare a silica coating. Sodium silicate, waterglass, is an inorganic compound that readily dissolves in water. Waterglass is synthesized commercially by reacting quartz sand with sodium hydroxide and/or sodium carbonate at elevated temperature and pressure. Given the wide abundance and inexpensive nature of these reactants, waterglass is perhaps the least expensive industrial silica source. The polar nature of the molecule (Si—O and Na+ ion pairs) on one hand makes it dissolve easily in water and on the other hand prevents the spontaneous formation of larger silica polycondensates or gelation due to electrostatic effects. In addition, it is easy to handle and unlike silicon alkoxides such as TEOS or TMOS, poses no flammability hazard. It is also chemically stable long-term under standard conditions of use and storage. Hence, this type of precursor combines most of the key advantages for the preparation of silica gels at an industrial scale.

Similar to alkoxide precursor-based silica gels, gelation of waterglass can be induced directly in a single step process by a simple neutralization or in a more elaborate two-step process (acidification/ion exchange followed by base addition).

In a two-step waterglass process, the sol used to prepare the gels consists of silicic acid (H2SiO3) and its oligomers polysilicic acids, which are produced by exchanging Na+ ions from the sodium silicate with H+. To remove sodium ions in the sodium silicate solution, a dilute sodium silicate solution is passed through a strongly acidic, cationic ion-exchange resin (e.g., Amberlyst). The pH of the native sodium silicate solution is above 11.5, but once passed through the ion exchange resin drops into the acidic range with typical values around 2.5. Following the ion exchange step, catalytic amounts of base, e.g., ammonium hydroxide (NH4OH), are added to induce gelation.

In the embodiment 200B, using the reverse micelle sol-gel reaction includes dissolving the quantum dots in a first non-polar solvent to form a first solution at 210A. Subsequently, the first solution is added along with a species such as, but not limited to, 3-aminopropyltrimethoxysilane (APTMS), 3-mercapto-trimethoxysilane, or a silane comprising a phosphonic acid or carboxylic acid functional group, to a second solution having a surfactant dissolved in a second non-polar solvent at 210B. Subsequently, sodium silicate is added to the second solution to start the gel formation at 210D. In one embodiment, an acid can be added to adjust the pH to an appropriate value to facilitate the gel formation. In another embodiment, potassium silicate is used instead of sodium silicate. In yet another embodiment, lithium silicate is used instead of sodium silicate. In another embodiment, no silane is added to the first solution, but sodium silicate, potassium silicate or lithium silicate is added to the second solution.

Thus, semiconductor quantum dots coated with silica according to the present invention may be made by a sol-gel reaction such as a reverse micelle method. As an example, FIG. 3B illustrates operations in a reverse micelle approach to coating a semiconductor structure, in accordance with an embodiment of the present invention. Referring to part A of FIG. 3B, a quantum dot heterostructure (QDH) 302 (e.g., a nanocrystalline core/shell pairing) has attached thereto one or more of TOPO ligands 304, TOP ligands 306, and Oleic Acid 305. Referring to part B, the plurality of TOPO ligands 304, TOP ligands 306, and Oleic acid 305 are exchanged with a plurality of Si(OCH3)3(CH2)3NH2 ligands 308. The structure of part B is then reacted with sodium silicate, potassium silicate, or lithium silicate, to form a silica coating 310 surrounding the QDH 302, as depicted in part C of FIG. 3B.

With respect to FIG. 2C, according to embodiment 200C, a quantum dot is formed 205 as described above, including, for example, at least one nanocrystalline shell and anisotropic nanocrystalline core. Then at 210 an insulator layer is formed to encapsulate the quantum dot structure. For example, in an embodiment, a layer of silica is formed using a reverse micelle sol-gel reaction. According to embodiment 200C, using the reverse micelle sol-gel reaction includes dissolving the quantum dots in a first non-polar solvent to form a first solution at 210A. Subsequently, the first solution is added along with a species such as, but not limited to, 3-aminopropyltrimethoxysilane (APTMS), 3-mercapto-trimethoxysilane, or a silane comprising a phosphonic acid or carboxylic acid functional group, to a second solution having a surfactant dissolved in a second non-polar solvent at 210B. Sodium silicate, potassium silicate or lithium silicate is first acidified by ion exchanging Na+ ions from the sodium silicate with H+ at 210E. The ion exchanged product plus ammonium hydroxide (NH4OH) are added to the second solution to start silica coating at 210F. In another embodiment, no silane is added to the first solution, but acidified sodium silicate, potassium silicate or lithium silicate and ammonium hydroxide are added to the second solution.

Thus, semiconductor quantum dots coated with silica according to the present invention may be made by a sol-gel reaction such as a reverse micelle method. As an example, FIG. 3C illustrates operations in a reverse micelle approach to coating a semiconductor structure, in accordance with an embodiment of the present invention. Referring to part A of FIG. 3C, a quantum dot heterostructure (QDH) 302 (e.g., a nanocrystalline core/shell pairing) has attached thereto one or more of TOPO ligands 304, TOP ligands 306, and Oleic Acid 305. Referring to part B, the plurality of TOPO ligands 304, TOP ligands 306, and Oleic acid 305 are exchanged with a plurality of Si(OCH3)3(CH2)3NH2 ligands 308. The structure of part B is then reacted with acidified sodium silicate, potassium silicate, or lithium silicate, and ammonium hydroxide (NH4OH) to form a silica coating 310 surrounding the QDH 302, as depicted in part C of FIG. 3C.

Silica Coating in Non-Polar Solvent Using Polymer Coated Quantum Dots.

With respect to FIG. 2D, according to embodiment 200D, a quantum dot is formed 205 as described above, including, for example, at least one nanocrystalline shell and anisotropic nanocrystalline core. Then at 215, quantum dots can be first coated with polymer(s) before silica coating at 220, taking advantage of the various chemical compositions and charges available of the polymer(s). In one embodiment, quantum dots can be first encapsulated with an amphiphilic polymer. The amphiphilic polymer can be a block polymer or a branched polymer that has both hydrophobic and hydrophilic moieties. In another embodiment, quantum dots can also be coated with a hydrophilic polymer via ligand exchange. The hydrophilic polymer can be polyacrylic acid, polyphosphonic acid, polyamines like polyallylamine and polyethylenimine, polythiolates, polyimidizoles or any polymer containing carboxylic, phosphonic acid, thiol, amine and/or imidizole.

An inorganic insulating layer can be grown on the quantum dots coated with polymer at 220. For example, a silica coating can be grown on aforementioned polymer coated quantum dots in a non-polar solvent as described above, using TEOS, sodium silicate, potassium silicate, lithium silicate or acidified metal silicate as precursor with or without the addition of silane in the first solution.

Silica Coating in Polar Solvent Using Polymer Coated Quantum Dots.

With respect to FIG. 2E, according to embodiment 200E, a quantum dot is formed 205 as described above, including, for example, at least one nanocrystalline shell and anisotropic nanocrystalline core. Then at 225, a water soluble polymer layer is formed, encapsulating the quantum dot to create a polymer coated quantum dot, before silica coating at 230. At 230, a water soluble polymer coated quantum dot can be coated with an additional insulator layer in a polar solvent or a mixture of polar solvents. In embodiment 200E, polymer coated water soluble quantum dots are dissolved in water. Subsequently, ammonium hydroxide and tetraorthosilicate (TEOS) are added to the solution to grow a silica layer around quantum dots.

In another embodiment, polymer coated water soluble quantum dots are dissolved in water. Subsequently sodium silicate, potassium silicate or lithium silicate is added to the solution to grow a silica layer around quantum dots. An acid can also be added as a catalyst to accelerate the reaction.

In another embodiment, polymer coated water soluble quantum dots are dissolved in water. Subsequently ion exchanged sodium silicate, potassium silicate or lithium silicate is added to the solution to grow a silica layer around quantum dots. A base such as ammonium hydroxide is also added as a catalyst to accelerate the reaction.

In another embodiment, polymer coated water soluble quantum dots are dissolved in a mixture of water and an alcohol (MeOH, EtOH, IPA). Subsequently, ammonium hydroxide and tetraorthosilicate (TEOS) are added to the solution to grow a silica layer around quantum dots.

In another embodiment, polymer coated water soluble quantum dots are dissolved in a mixture of water and an alcohol (MeOH, EtOH, IPA). Subsequently, sodium silicate, potassium silicate, or lithium silicate is added to the solution to grow a silica layer around quantum dots. An acid can also be added as a catalyst to accelerate the reaction.

In another embodiment, polymer coated water soluble quantum dots are dissolved in a mixture of water and an alcohol (MeOH, EtOH, IPA). Subsequently, ion exchanged sodium silicate, potassium silicate, or lithium silicate is added to the solution to grow a silica layer around quantum dots. A base such as ammonium hydroxide is also added as a catalyst to accelerate the reaction.

For all the above-described embodiments relating to growing a silica layer in polar solvent using Polymer coated quantum dots, the appropriate silane usually has a charge opposite to that of the water soluble polymer in order to facilitate the initial growth of the silica layer around quantum dots.

In another aspect, quantum dot composite compositions are described. For example, the quantum dots (including coated quantum dots) described above may be embedded in a matrix material to make a composite using a plastic or other material as the matrix. In an embodiment, composite compositions including matrix materials and silica coated core/shell quantum dots having photoluminescence quantum yields between 90 and 100% are formed. Such quantum dots may be incorporated into a matrix material suitable for down converting in LED applications.

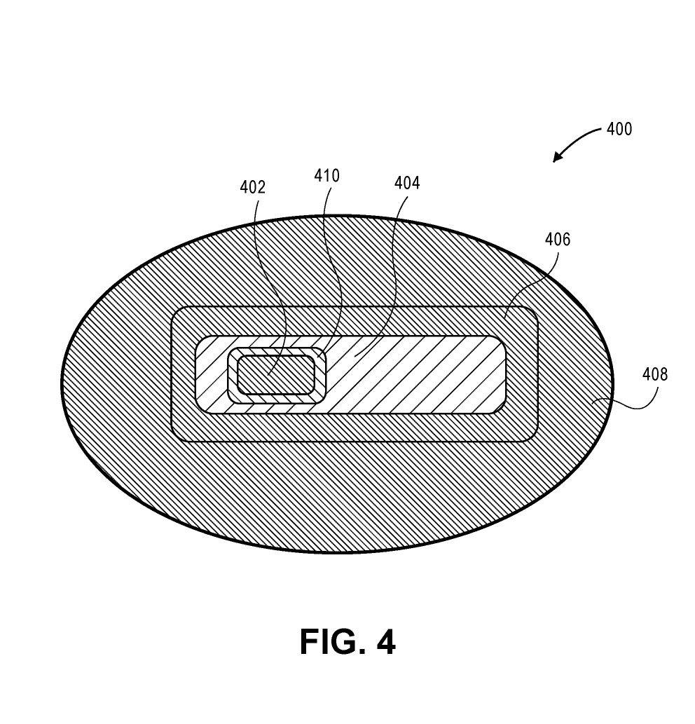

In another example, and as illustrated in FIG. 4 below, a semiconductor structure has a nanocrystalline core and nanocrystalline shell pairing with one compositional transition layer, in accordance with an embodiment of the present invention.

Referring to FIG. 4, a semiconductor structure 400 includes a nanocrystalline core 402 composed of a first semiconductor material. A nanocrystalline shell 404 composed of a second, different, semiconductor material at least partially surrounds the nanocrystalline core 402. A compositional transition layer 410 is disposed between, and in contact with, the nanocrystalline core 402 and nanocrystalline shell 404. The compositional transition layer 410 has a composition intermediate to the first and second semiconductor materials.

In an embodiment, the compositional transition layer 410 is an alloyed layer composed of a mixture of the first and second semiconductor materials. In another embodiment, the compositional transition layer 410 is a graded layer composed of a compositional gradient of the first semiconductor material proximate to the nanocrystalline core 402 through to the second semiconductor material proximate to the nanocrystalline shell 404. In either case, in a specific embodiment, the compositional transition layer 410 has a thickness approximately in the range of 1.5-2 monolayers. Exemplary embodiments include a structure 400 where the first semiconductor material is cadmium selenide (CdSe), the second semiconductor material is cadmium sulfide (CdS), and the compositional transition layer 410 is composed of CdSexSy, where 0<x<1 and 0<y<1, or where the first semiconductor material is cadmium selenide (CdSe), the second semiconductor material is zinc selenide (ZnSe), and the compositional transition layer 410 is composed of CdxZnySe, where 0<x<1 and 0<y<1.

In an embodiment, the nanocrystalline shell 404 completely surrounds the nanocrystalline core 402, as depicted in FIG. 4. In an alternative embodiment, however, the nanocrystalline shell 404 only partially surrounds the nanocrystalline core 402, exposing a portion of the nanocrystalline core 402. Furthermore, in either case, the nanocrystalline core 402 may be disposed in an asymmetric orientation with respect to the nanocrystalline shell 404. In one or more embodiments, semiconductor structures such as 400 are fabricated to further include a nanocrystalline outer shell 406 at least partially surrounding the nanocrystalline shell 404. The nanocrystalline outer shell 406 may be composed of a third semiconductor material different from the first and second semiconductor materials, i.e., different from the materials of the core 402 and shell 404. The nanocrystalline outer shell 406 may completely surround the nanocrystalline shell 404 or may only partially surround the nanocrystalline shell 404, exposing a portion of the nanocrystalline shell 404. Lastly, an insulator layer 408 encapsulates the shell 406.

In another embodiment, a network of quantum dots may be formed by fusing together the insulator coatings of a plurality of insulator coated quantum dots. For example, in accordance with an embodiment of the present invention, insulator coatings of discrete passivated quantum dots are fused together to form a substantially rigid network of quantum dots where each quantum dot is isolated from other quantum dots in the network by the fused insulator coating. In one such embodiment, fusing together the insulator coatings of discretely passivated quantum dots into a fused network provides improved optical and reliability performance of the resulting structure as compared with the starting discretely passivated quantum dots. In one such embodiment, a chemical base is used to improve the optical performance of silica coated materials by enabling the fusing of the insulator coatings surrounding a plurality of quantum dots. In a specific embodiment, the insulator coating is a silica coating and a base such as potassium hydroxide (KOH) is used to fuse together the silica coatings of a plurality of individually and discretely coated quantum dots. The result is a substantially rigid silica-based network of quantum dots. The amount of base material is scaled with the amount of silica in the reaction. In general, the approaches described herein have important applications for improving the optical and reliability performance of quantum dots or even other phosphor materials having an insulator coating and which are embedded in a matrix. In one such embodiment, the quantum dots or other phosphor materials are first individually coated with one or more insulator layers and then the coated materials are fused to form an insulator network that can be embedded in a matrix. In other embodiments, the insulator network is formed directly on the quantum dots or other phosphor materials.

In an embodiment, then, with respect to using colloidal semiconductor nanocrystals, also known as quantum dots, as downshifting fluorescent materials for LED lighting and/or display technologies, quantum dots are individually coated with a silica insulator layer. The presence of the silica coating improves the performance of the quantum dots when they are subsequently embedded in a polymer film and subjected to various stress tests. Applications include LED lighting applications and/or display configurations. The use of base (such as KOH, NaOH or other similar materials) provides a fused network of the silica coated quantum dots to improve the optical performance of quantum dot materials. As described below, in particular embodiments, the scaling of the amount of KOH or other base with silica content is balanced to achieve optimal performance of the coated/fused quantum dots.

In an embodiment, a method of fabricating a semiconductor structure involves forming a mixture including a plurality of discrete semiconductor quantum dots. Each of the plurality of discrete semiconductor quantum dots is discretely coated by an insulator layer. The method also involves adding a base to the mixture to fuse the insulator layers of each of the plurality of discrete quantum dots, providing an insulator network. Each of the plurality of discrete semiconductor quantum dots is spaced apart from one another by the insulator network. The base may be comprises of, but is not limited to, LiOH, RbOH, CsOH, MgOH, Ca(OH)2, Sr(OH)2, Ba(OH)2, (Me)4NOH, (Et)4NOH, or (Bu)4NOH.

In another embodiment, a method of fabricating a semiconductor structure involves forming a mixture including a plurality of discrete semiconductor quantum dots. Each of the plurality of discrete semiconductor quantum dots is discretely coated by an insulator material. The method also involves adding a base to the mixture to fuse the insulator coating of each of the plurality of discrete nanocrystals, providing an insulator network. Each of the plurality of discrete semiconductor quantum dots is spaced apart from one another by the insulator network. The base may be comprised of, but is not limited to, LiOH, RbOH, CsOH, MgOH, (Me)4NOH, (Et)4NOH, or (Bu)4NOH, and adding the base to the mixture involves adding one mole of the base for every two moles of the insulator material. The method also involves adding free silica to the mixture.

In another embodiment, a method of fabricating a semiconductor structure involves forming a mixture including a plurality of discrete semiconductor quantum dots. Each of the plurality of discrete semiconductor quantum dots is discretely coated by an insulator material. The method also involves adding a base to the mixture to fuse the insulator coating of each of the plurality of discrete quantum dots, providing an insulator network. Each of the plurality of discrete semiconductor quantum dots is spaced apart from one another by the insulator network. The base may be comprised of, but is not limited to, Ca(OH)2, Sr(OH)2 or Ba(OH)2, and adding the base to the mixture involves adding one mole of the base for every four moles of the insulator material. The method also involves adding free silica to the mixture.

In accordance with one or more embodiments herein, an alternative to altering seed size for tuning the emission of a seeded rod emitter architecture is provided. More particularly, instead of changing seed size, the seed composition is changed by alloying either the entire seed (in one embodiment) or some portion of the seed (in another embodiment) with a higher bandgap material. In either case, the general approach can be referred to as an alloying of the seed or nanocrystalline core portion of a heterostructure quantum dot. By alloying the seed or nanocrystalline core, the bandgap can be changed without changing the size of the seed or core. As such, the emission of the seed or core can be changed without changing the size of the seed or core. In one such embodiment, the size of the seed is fixed at the optimum size of a red-emitting seed, or roughly 4 nanometers. The fixed sized means that the size of the rod and the subsequent synthetic operations may not need to be substantially re-optimized or altered as the emission target of the quantum dots is changed.

Accordingly, in one or more embodiments described herein, optimum physical dimensions of a seeded rod are maintained as constant while tuning the emission peak of the heterostructure quantum dot. This can be performed without changing the dimensions of the seed (and therefore the rod) for each emission color. In a particular embodiment, a quantum dot includes an alloyed Group II-VI nanocrystalline core. The quantum dot also includes a Group II-VI nanocrystalline shell composed of a semiconductor material composition different from the alloyed Group II-VI nanocrystalline core. The Group II-VI nanocrystalline shell is bonded to and completely surrounds the alloyed Group II-VI nanocrystalline core. In one such embodiment, the alloyed Group II-VI nanocrystalline core is composed of CdSenS1-n (0<n<1), and the Group II-VI nanocrystalline shell is composed of CdS. In a specific embodiment, the alloyed Group II-VI nanocrystalline core has a shortest diameter of greater than approximately 2 nanometers, and the quantum dot has an exciton peak less than 555 nanometers. In a particular embodiment, the alloyed Group II-VI nanocrystalline core has a shortest diameter of approximately 4 nanometers, and the quantum dot has an exciton peak less than 555 nanometers, as is described in greater detail below

Perhaps more generally, in an embodiment, a quantum dot includes a semiconductor nanocrystalline core of arbitrary composition. The quantum dot also includes any number of semiconductor nanocrystalline shell(s). The semiconductor nanocrystalline shell(s) is/are bonded to and completely surrounds the semiconductor nanocrystalline core. In one such embodiment, the semiconductor nanocrystalline core is composed of a first Group II-VI material, and the binary semiconductor nanocrystalline shell is composed of a second, different, Group II-VI material. In one such embodiment, the first Group II-VI material is CdSenS1-n (0<n<1), and the second Group II-VI material is CdS.

One or more embodiments described herein involve fabrication of a semiconductor hetero-structure. The semiconductor hetero-structure has a nano-crystalline core composed of a group semiconductor material. A nano-crystalline shell composed of a second, different, semiconductor material at least partially surrounds the nano-crystalline core. For example, the nano-crystalline shell may be composed of a different group I-III-VI semiconductor material or of a group II-VI semiconductor material.

In one such embodiment, the above described nano-crystalline core/nano-crystalline shell pairing has a photoluminescence quantum yield (PLQY) of greater than approximately 60%. In another, or same, such embodiment, the nano-crystalline core/nano-crystalline shell pairing provides a Type I hetero-structure. One or more embodiments described herein are directed to hetero-structure systems having distinct group I-III-VI material cores. In an exemplary embodiment, a sphere or rod-shaped core/shell quantum dot is fabricated to have a sharp compositional interface between the core and shell or a graded/alloyed interface between core and shell.

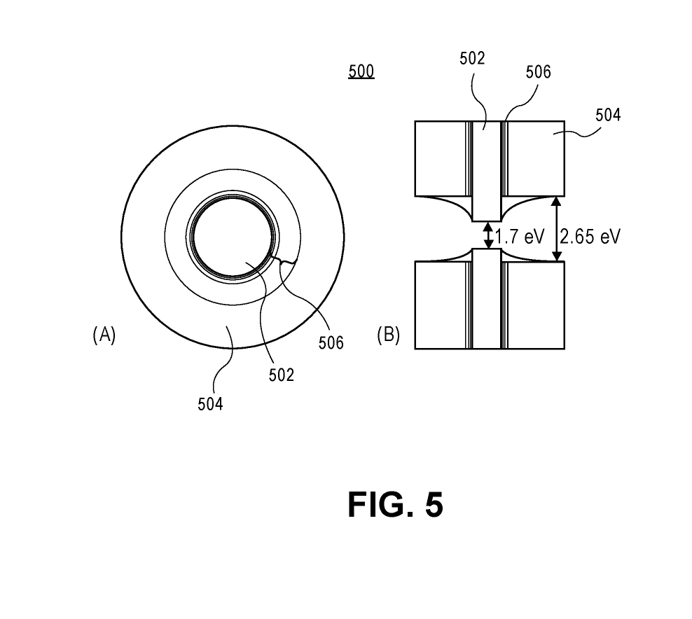

FIG. 5 illustrates an axial cross-sectional view (A) of a spherical nano-particle 500, in accordance with an embodiment of the present invention. Referring to FIG. 5, an alloy region 506 is included between the core 502 and shell 504 of 500. As shown in part (B) of FIG. 5, in one embodiment, the nano-particle 500 demonstrates type I hetero-structure behavior, with excitons preferentially recombining in the core 502 of the nano-crystal 500 due to the smaller, nested bandgap of the seed. Optionally, additional layers of material may be added, including additional epitaxial layers or amorphous inorganic and organic layers. Other suitable embodiments are described below.

In an embodiment, systems described herein include a nano-crystalline core emitter having a direct, bulk band gap approximately in the range of 1-2.5 eV. Exemplary cores include a group I-III-VI semiconductor material based on silver gallium sulfide having a stoichiometry of approximately AgGaS2. In one such embodiment, the nano-crystalline core has a peak emission approximately in the range of 475-575 nanometers.

In one or more embodiments, the nano-crystalline core and nano-crystalline shell pairings described herein have a lattice mismatch of equal to or less than approximately 10%. In some embodiments, less than approximately 6% mismatch is preferable, but up to approximately 10% can be workable. In particular embodiments, the mismatch is less than approximately 4% mismatch, as seen in successful Cd-based systems.

One or more embodiments described herein is directed to a hetero-structure core/shell pairing that is cadmium-free. For example, with reference to the above described nano-crystalline core and nano-crystalline shell pairings, in an embodiment, the first (core) material is a group I-III-VI semiconductor material. In one such embodiment, the second (shell) semiconductor material is a second group I-III-VI material. For example, a suitable I-III-VI/I-III-VI core/shell pairing can include, but is not limited to, copper indium sulfide (CIS)/silver gallium sulfide (AgGaS2), copper indium selenide (CISe)/AgGaS2, copper gallium selenide (CuGaSe2)/copper gallium sulfide (CuGaS2), or CuGaSe2/AgGaS2. In another such embodiment, the second (shell) semiconductor material is a group II-VI material. For example, a suitable I-III-VI/II-VI core/shell pairing can include, but is not limited to, copper indium sulfide (CIS)/zinc selenide (ZnSe), CIS/zinc sulfide (ZnS), copper indium selenide (CISe)/ZnSe, CISe/ZnS, copper gallium selenide (CuGaSe2)/ZnSe, CuGaSe2/ZnS, silver gallium sulfide (AgGaS2)/ZnS, AgGaS2/ZnSe, or silver gallium selenide (AgGaSe2)/ZnS, AgGaSe2/ZnSe.

In an embodiment, the semiconductor hetero-structure further includes a nano-crystalline outer shell composed of a third semiconductor material different from the core and shell semiconductor materials. The third semiconductor material at least partially surrounding the nano-crystalline shell and, in one embodiment, the nano-crystalline outer shell completely surrounds the nano-crystalline shell. In a particular embodiment, the second (shell) semiconductor material one such as, but not limited to, zinc selenide (ZnSe), silver gallium sulfide (AgGaS2) or copper gallium sulfide (CuGaS2), and the third (outer shell) semiconductor material is zinc sulfide (ZnS).

While the shape of the core of the quantum dot depicted in Fig. # is that of a rod, it is appreciated that the methods described herein are not limited by the shape of the quantum dot and could be applied to coated quantum dots of multiple shapes, including spheres, rods, tetrapods, teardrops, sheets, etc. It is not limited by the composition of the quantum dot and can be applied to quantum dots made from a single material or multiple materials in either a core/shell/optional shell/optional shell configuration or an alloyed composition. The semiconductor materials may be selected from the Group II-VI compounds, Group III-V compounds, group IV-IV compounds, group I-III-VI compounds, or any alloy thereof. More specifically the semiconductor materials may be chosen from ZnO, ZnS, ZnSe, ZnTe, CdO, CdS, CdSe, CdTe, HgS, HgSe, HgTe, HgO, AlN, AlP, AlAs, AlSb, GaN, GaP, GaAs, GaSb, GaSe, InN, InP, InAs, Insb, TlN, TlP, TlAs, TlSb, PbS, PbSe, PbTe, MgO, MgS, MgSe, alloys thereof, and mixtures thereof.

What is claimed is:

1. A method of fabricating a semiconductor structure, comprising:
forming a quantum dot; and
forming an insulator layer of silica encapsulating the quantum dot to create a coated quantum dot, using a reverse micelle sol-gel reaction, wherein the reverse micelle sol-gel reaction includes:
dissolving the quantum dot in a first non-polar solvent to form a first solution;
adding the first solution to a second solution having a surfactant dissolved in a second non-polar solvent; and
adding ammonium hydroxide and tetraorthosilicate (TEOS) to the second solution.

2. The method of claim 1 wherein adding the first solution to the second solution further comprises adding to the second solution a species selected from the group of: 3-aminopropyltrimethoxysilane (APTMS), 3-mercapto-trimethoxysilane, and a silane comprising a phosphonic acid or carboxylic acid functional group.

3. The method of claim 1, wherein forming a quantum dot comprises:
forming a nanocrystalline core from a first semiconductor material;
forming at least one nanocrystalline shell from a second, different, semiconductor material that at least partially surrounds the nanocrystalline core, wherein the nanocrystalline core and the nanocrystalline shell form the quantum dot.

4. A method of fabricating a semiconductor structure, comprising:
forming a quantum dot; and
forming an insulator layer of silica encapsulating the quantum dot to create a coated quantum dot, using a reverse micelle sol-gel reaction, wherein the reverse micelle sol-gel reaction includes:
dissolving the quantum dot in a first non-polar solvent to form a first solution;
adding the first solution to a second solution having a surfactant dissolved in a second non-polar solvent; and,
adding sodium silicate, potassium silicate, or lithium silicate to the second solution.

5. The method of claim 4, wherein forming a quantum dot comprises:
forming a nanocrystalline core from a first semiconductor material;
forming at least one nanocrystalline shell from a second, different, semiconductor material that at least partially surrounds the nanocrystalline core, wherein the nanocrystalline core and the nanocrystalline shell form the quantum dot.

6. The method of claim 4, wherein adding the first solution to the second solution further comprises adding to the second solution a species selected from the group of: 3-aminopropyltrimethoxysilane (APTMS), 3-mercapto-trimethoxysilane, and a silane comprising a phosphonic acid or carboxylic acid functional group.

7. The method of claim 4, wherein the sodium silicate, potassium silicate, or lithium silicate is added to the second solution as a silica precursor to start a gel formation; and
wherein the reverse micelle sol-gel reaction further includes adding acid to the second solution adjust pH to facilitate the gel formation.

8. A method of fabricating a semiconductor structure, comprising:
forming a quantum dot; and
forming an insulator layer encapsulating the quantum dot to create a coated quantum dot, using a reverse micelle sol-gel reaction, wherein the reverse micelle sol-gel reaction includes:
dissolving the quantum dot in a first non-polar solvent to form a first solution;
adding the first solution to a second solution having a surfactant dissolved in a second non-polar solvent;
acidifying sodium silicate, potassium silicate, or lithium silicate; and
adding the acidified sodium silicate, potassium silicate, or lithium silicate, and ammonium hydroxide, to the second solution.

9. The method of claim 8, wherein adding the first solution to the second solution further includes adding to the second solution a species selected from the group of: 3-aminopropyltrimethoxysilane (APTMS), 3-mercapto-trimethoxysilane, and a silane comprising a phosphonic acid or carboxylic acid functional group.

10. The method of claim 8 wherein acidifying sodium silicate, potassium silicate, or lithium silicate comprises ion exchanging Na+ ions from the sodium silicate, potassium silicate, or lithium silicate, with H+.

11. A method of fabricating a semiconductor structure, comprising:
forming a quantum dot;
forming a polymer layer encapsulating the quantum dot to create a polymer coated quantum dot; and
forming an inorganic insulator layer of silica encapsulating the polymer coated quantum dot to create an insulator coated quantum dot.

12. The method of claim 11, wherein forming the polymer layer encapsulating the quantum dot to create a polymer coated quantum dot comprises forming an amphiphilic polymer layer encapsulating the quantum dot to create a polymer coated quantum dot, and wherein the amphiphilic polymer is a block polymer or a branched polymer that has both hydrophobic and hydrophilic moieties.

13. The method of claim 11, wherein forming the polymer layer encapsulating the quantum dot to create a polymer coated quantum dot comprises forming a hydrophilic polymer layer via ligand exchange, and wherein the hydrophilic polymer is selected from a group consisting of polyacrylic acid, polyphosphonic acid, polyamines including polyallylamine and polyethylenimine, polythiolates, polyimidizoles, and polymers containing carboxylic, phosphonic acid, thiol, amine and/or imidizole.

14. A method of fabricating a semiconductor structure, comprising:
forming a quantum dot;
forming a water soluble polymer layer encapsulating the quantum dot to create a polymer coated quantum dot; and
forming an insulator layer of silica encapsulating the quantum dot to create a insulator coated quantum dot, comprising:
dissolving the polymer coated quantum dot in water, or in a mixture of water and an alcohol selected from the group consisting of MeOH, etOH, IPA, to form a first solution; and
adding ammonium hydroxide and tetraorthosilicate (TEOS), or one of sodium silicate, potassium silicate, and lithium silicate and an acid as a catalyst, or one of an ion exchanged sodium silicate, potassium silicate, and lithium silicate and a base as a catalyst to the first solution.
